(19) United States
(12) Patent Application Publication
(10) Pub. No.: US 2015/0145068 A1
(43) Pub. Date: May 28, 2015

(54) STRUCTURE OF FinFETs

(71) Applicant: NATIONAL APPLIED RESEARCH LABORATORIES, Taipei City (TW)

(72) Inventors: MIN-CHENG CHEN, HSINCHU (TW); CHIA-HUA HO, HSINCHU CITY (TW); FU-LIANG YANG, HSINCHU CITY (TW)

(73) Assignee: NATIONAL APPLIED RESEARCH LABORATORIES, Taipei City (TW)

(21) Appl. No.: 14/265,502

(22) Filed: Apr. 30, 2014

(30) Foreign Application Priority Data
Nov. 25, 2013 (TW) 102142814

(51) Int. Cl. H01L 29/78; H01L 21/308

(52) U.S. Cl. CPC H01L 29/785; H01L 21/3083
USPC 257/401

(57) ABSTRACT

The present invention relates to a method for fabricating FinFETs and the structure thereof. The present invention uses an additional mask to define regions forming semiconductor fins having high semiconductor-fin height. By making use of multiple etching processes of the insulating layer, structures with differences in the height of semiconductor fins are achieved. The method can be combined with current process for semiconductor-based FinFETs for overcoming effectively the problem of electron-channel-width quantization effect as well as improving the performance of FinFETs.

### FIELD OF THE INVENTION

The present invention relates generally to a method for fabricating FinFETs and the structure thereof, and particularly to adopt an extra mask for enabling FinFETs to have different heights of semiconductor fins and reducing the width quantization effect for electron channels.

### BACKGROUND OF THE INVENTION

The FinFET is a novel, multi-channel, and three-dimensional transistor; it improves the performance significantly and reduces the power consumption, much superior to current planar CMOS devices. In a FinFET, the gate of the device surrounds and wraps the channel, giving superior electron characteristics, providing lower threshold voltages and higher performance, and reducing leakage and dynamic power consumption.

Through the particularity of fin-shaped structures of FinFETs in the three-dimensional space, the Moore's law is able to extend. FinFETs differ completely from traditional transistors, which endeavor in linear miniaturization on a plane. When planar transistors are shrunk below 20 nanometers, the gate control on the channel is reduced, resulting in increases in leakage currents from the drain to the source. In addition, unnecessary short-channel effects are induced; transistors will be turned off improperly and increasing standby power consumption of electronic devices. Fortunately, the three-dimensional FinFET technology emerges and functions. In a FinFET structure, because the channel is wrapped by three layers of gate, the leakage current in the turn-off state can be suppressed more effectively.

Nonetheless, three-dimensional FinFETs also elicit some changes in design. In particular, in the planar transistor domain, the width of transistors can be changed arbitrarily for managing the driving current. Contrarily, for FinFETs, the driving current can be changed only by adding or reducing the number of fin-shaped structures integrally. This is the so-called width quantization problem.

The U.S. patent publication number US 20080128797 discloses a FinFET having multiple fin heights. the fabricated FinFET, the fin-shaped structures have different heights. The purpose of this structure is, without changing the characteristics of fin-shaped structures, to make the driving current vary in non-integer times, namely, to improve the width quantization problem. According to the invention, the mask for oxygen implantation includes different thickness for controlling the number of implanted oxygen atoms in different blocks of the semiconductor layer. Then, after annealing, a buried oxide layer with a specific structure is formed. Afterwards, remove the non-buried oxide layer at a time and a fin-shaped structure having different exposed heights is given.

The method of improving the width quantization effect by using different fin heights is a very effective method. The present invention solves the problems of integrating to existing silicon-based process for FinFETs for mass production. Thereby, difficult or high-cost semiconductor technologies should be avoided; the performance of FinFETs is enhanced effectively by using the fabrication processes totally compatible to current semiconductor manufacturing flow.

### SUMMARY

An objective of the present invention is to provide a method for fabricating FinFETs, which uses an additional mask process to make the thickness of the insulating layer in a FinFET vary. Thereby, there will be high fins and short fins thanks to different lengths of the exposed semiconductor fins above the insulating layer.

Another objective of the present invention is to provide a method for fabricating FinFETs, which uses an additional mask process to change the length of semiconductor fins nonuniformly so that more linear choices for the effective width of FinFETs are provided and improving the width quantization effect.

Still another objective of the present invention is to provide a method for fabricating FinFETs, which uses an additional mask process to reduce the area occupied by a single FinFET given the same layout width because a high fin has the structural characteristics of higher fin height and shorter fin width. Thereby, while fabricating electronic devices such as static random access memory (SRAM), no advanced lithography technology is required. Instead, based on increased density of layout, further device miniaturization can be performed.

A further objective of the present invention is to provide a structure of FinFETs, which has a projective taper structure at the junction between the bottom of the semiconductor fin and the insulating layer. By taking advantage of the difference in the height of semiconductor fins covered by tapers, the control of effective width can be more flexible, and thus improving the width quantization effect more effectively.

In order to achieve the objectives described above, the present invention discloses a method for fabricating FinFETs and the structure thereof. The method comprises steps of etching a semiconductor substrate, and forming a plurality of semiconductor fins with identical heights on the semiconductor substrate; disposing an insulating layer on the semiconductor substrate, and exposing the plurality of semiconductor fins; and etching the insulating layer partially using a mask, and forming a first block and a second block having a difference in height on the insulating layer; where the heights of the plurality of semiconductor fins exposed above the insulating layer are different. Based on this fabrication method, by further using additional masks, more blocks other than the first and second blocks described above can be formed, and enabling more variations in the height of semiconductor fins. Regarding to the structure, by the process of wet etching, taper structures are formed at the junctions between semiconductor fins and the insulating layer. Differences in the height of semiconductor fins result in differences in the height of taper structures covering the semiconductor fins, and thus providing effective widths with more linearity. By processing and preparing the novel structure according to the fabrication process, the present invention makes a breakthrough in the evolution of FinFETs.

### BRIEF DESCRIPTION OF THE DRAWINGS

FIG. 1 shows a flowchart according a preferred embodiment of the present invention;

FIG. 2 shows a structural schematic diagram of disposing a patterned mask on a semiconductor substrate according to the present invention;

FIG. 3 shows a structural schematic diagram of etching the semiconductor substrate and forming a plurality of semiconductor fins with identical heights according to the present invention;

FIG. 4 shows a structural schematic diagram of disposing an insulating layer on the semiconductor substrate according to the present invention;

FIG. 5 shows a structural schematic diagram of etching the insulating layer and exposing the semiconductor fins according to the present invention;

FIG. 6 shows a structural schematic diagram of etching the insulating layer partially using a mask according to the present invention;

FIG. 7 shows a structural schematic diagram of forming a first block and a second block having a difference in height on the insulating layer according to the present invention;

FIG. 8 shows a structural schematic diagram of changing the location of the mask and re-etching the insulating layer partially according to the present invention;

FIG. 9 shows a structural schematic diagram of forming the first block, the second block, and a third block having differences in height on the insulating layer according to the present invention;

FIG. 10 shows a structural schematic diagram of the FinFET according to the present invention;

FIG. 11 shows a structural schematic diagram of the taper structures and the heights of the tapers according to the present invention; and

FIG. 12 shows a structural schematic diagram of the insulating layer 2 with a non-gradually-varying thickness according to the present invention.

### DETAILED DESCRIPTION

In order to make the structure and characteristics as well as the effectiveness of the present invention to be further understood and recognized. the detailed description of the present invention is provided as follows along with embodiments and accompanying figures.

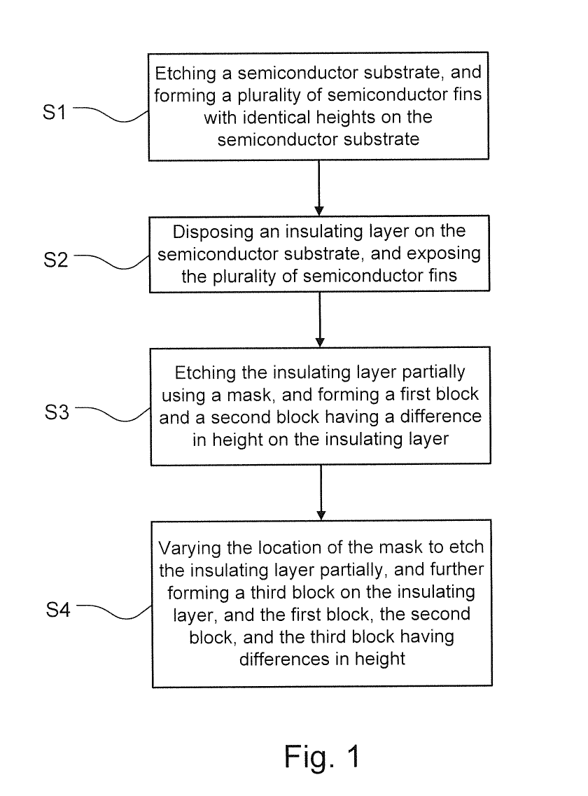

First, please refer to FIG. 1, which shows the technical characteristics of the process steps according to the present invention. The method comprises steps of:
Step S1: Etching a semiconductor substrate, and forming a plurality of semiconductor fins with identical heights on the semiconductor substrate;
Step S2: Disposing an insulating layer on the semiconductor substrate, and exposing the plurality of semiconductor fins;
Step S3: Etching the insulating layer partially using a mask, and forming a first block and a second block having a difference in height on the insulating layer; and
Step S4: Varying the location of the mask to etch the insulating layer partially, and further forming a third block on the insulating layer, and the first block, the second block, and the third block having differences in height.

According to the present invention, the critical step is the process using at least an additional mask for mitigating the problem of width quantization. Consequently, the method for a designer to change the driving current is no longer limited to increasing or reducing the number of semiconductor fins only. Using the method disclosed in the present invention, the difference in layout width for semiconductor fins can be varied in non-integer multiples. The material of the semiconductor substrate can be silicon, germanium, carbon, group-III elements, or group-V elements.

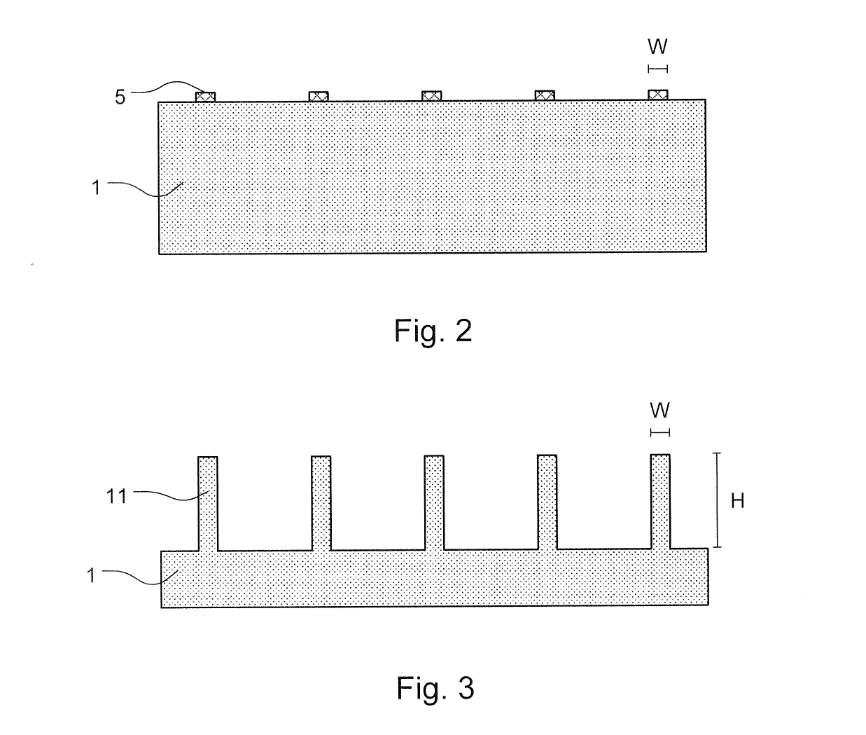

To describe the variations of the FinFET fabricated according to the present invention, please refer to FIG. 2 first. A semiconductor substrate 1 is etched in step S1. The width W and locations of the semiconductor fins to be etched on the semiconductor substrate 1 will be defined on the semiconductor substrate via a patterned mask 6 in advance. The etched semiconductor substrate 1 is shown in FIG. 3. A plurality of projective fin-shaped structures, which are just the semiconductor fins 11 having three-dimensional functions in FinFETs, are formed on the etched surface. The semiconductor-fin heights H of the plurality of semiconductor fins 11 are identical at this stage.

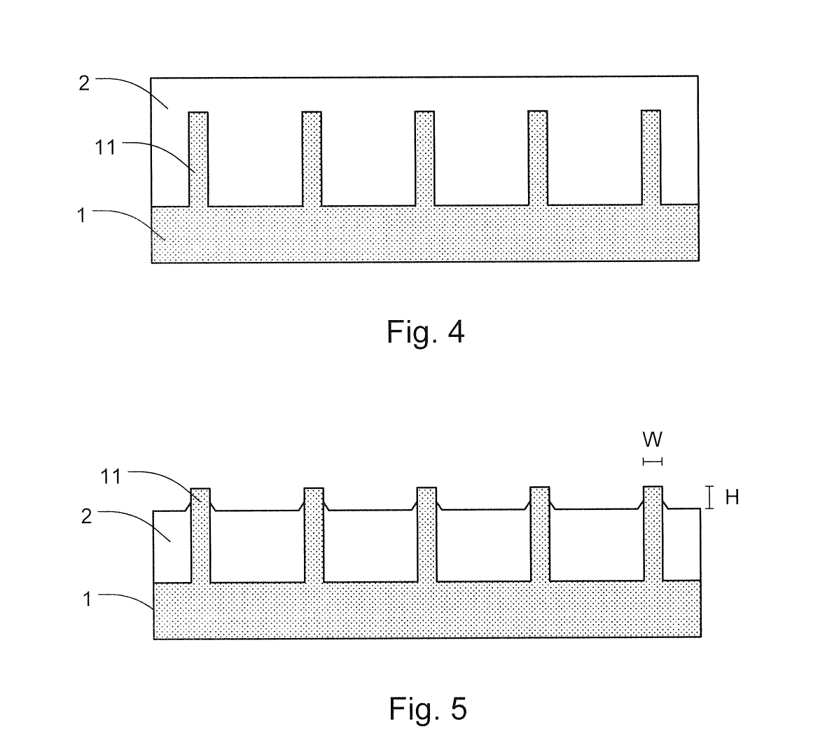

Next, please refer to FIG. 4. An insulating layer 2 will be disposed on the surface of the semiconductor substrate 1 being etched and forming the semiconductor fins 11. Generally, a deposition method is adopted for depositing an oxide material on the semiconductor substrate 1 and covering the plurality of semiconductor fins 11. For example, the high-density plasma chemical vapor deposition (HDPCVD) is used for depositing silicon dioxide on the semiconductor substrate 1.

Afterwards, this insulating layer 2 is etched and exposing the originally covered semiconductor fins 11, as shown in FIG. 5. In addition, owing to the unetched insulating layer 2, the semiconductor-fin height H is shortened. The remaining insulating layer 2 fills the trenches between the semiconductor fins 11 and is used as shallow trench isolation (STI).

In the method for fabricating FinFETs according to the prior art, because the structures of exposed semiconductor fins 11 are identical, the layout width, namely, the sum of two semiconductor-fin height H and one semiconductor-fin width W, will be the same for all semiconductor fins. Consequently, the variation of driving current is purely influenced by increase or reduction in the number of the semiconductor fins 11 with fixed multiples. Nonetheless, the fabrication process according to the present invention will further change the semiconductor-fin height H for reducing the influence of the width quantization effect described above.

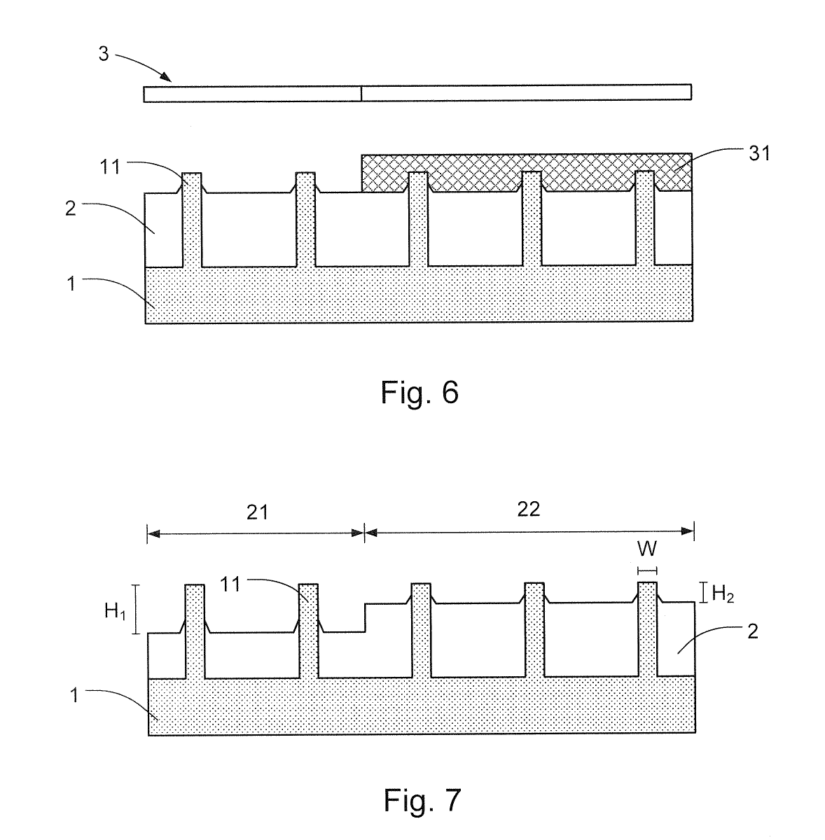

Please refer to FIG. 6 and FIG. 7. A mask 3 is first disposed. By using the mask 3, a patterned first photoresist layer 31 covers a portion of the insulating layer 2 and the semiconductor fins 11 in that region. Then etching is performed to remove partially the insulating layer 2 not covered by the first photoresist layer 31. The etching process can be dry or wet etching. In particular, wet etching produces the taper structures, which can improve effectively the width quantization effect (as described later). After the partial etching process, a first block 21 and a second block 22 having a difference in height is thus formed on the insulating layer 2. In addition, the semiconductor-fin heights H of the semiconductor fins 11 in the first and second blocks 21, 22 will be different. The different of the semiconductor-fin heights of the semiconductor fins 11 exposed above the insulating layer 2 between the first and second block 21, 22 is equal or higher than 25% of the semiconductor-fin height of the semiconductor fins 11 exposed above the insulating layer 2 in the first block 21.

By using the extra mask 3, the semiconductor-fin height H according to the original process is no longer fixed. Take FIG. 6 for example. If the semiconductor-fin height H₁ in the first block 21 is the commonly-used standard height according to the prior art, the shorter semiconductor-fin height H₂ in the second block 22 can be regarded as further division of the semiconductor-fin height H₁. Thereby, the ratios of effective width to layout width for FinFETs can approach the proportional curve for planar MOSFETs.

For example, when the semiconductor fins 11 in the first block 21 belong to the standard model commonly used according to the prior art and the layout width of a single semiconductor fin 11 is 0.06 um, general FinFETs can only provide specifications of 0.06 um, 0.12 um, 0.18 um, etc. However, if the semiconductor fins 11 having the layout width of 0.02 um in the second block 22 can be used as well, specifications of 0.06 um, 0.08 um, 0.10 um, etc. will be provided. Thereby, thanks to the more linear form, the influence of width quantization can be mitigated.

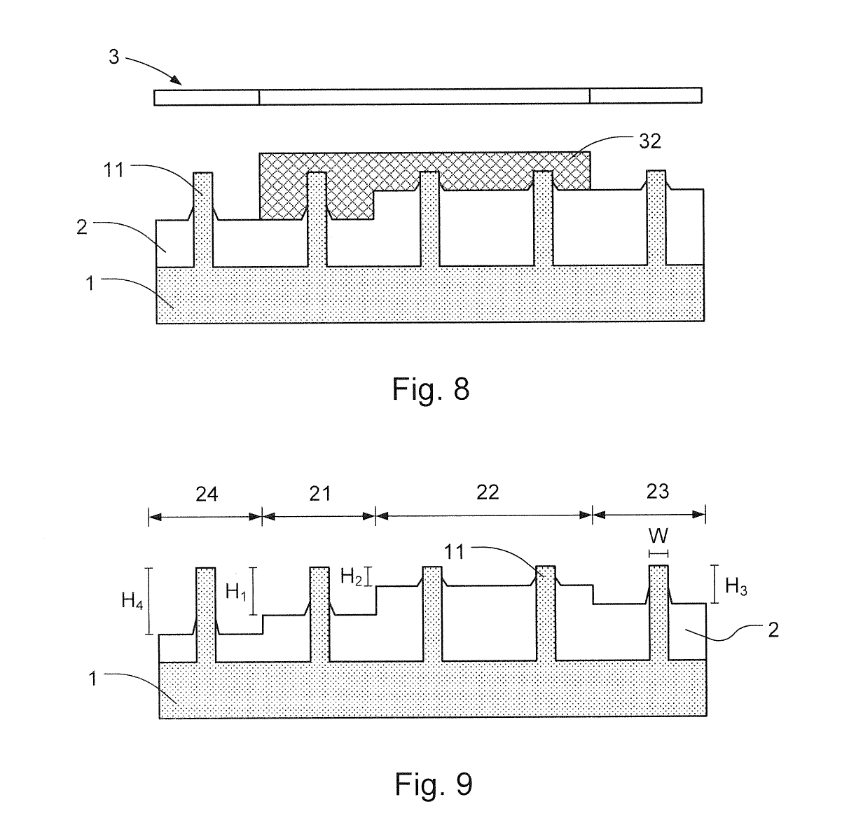

Please refer to FIG. 8. The method according to the present invention can further provide a FinFET structure more flexible and practical than the previous one by changing the location of the mask 3 can re-etch partially the insulating layer 2. As shown in the figure, after removing the first photoresist layer 31 in FIG. 6, a second photoresist layer 32 is coated on the insulation layer 2. The second photoresist layer 32 is different from the first photoresist layer 31 owing to differences in the area, pattern, or location of the mask 3. Hence, no completely repeated etching process will occur on the insulating layer 2. After the re-etching, at least a third block 23 will be formed on the insulating layer 2. In addition, differences in height occur between the third block 23 and the original first and second blocks 21, 22.

Please refer to FIG. 9. The semiconductor-fin heights H of the semiconductor fins 1 exposed above the insulating layer 2 in the first, second, and third blocks 21, 22, 23 are different. The semiconductor-fin heights H₁, H₂ do not change due to the shelter of the second photoresist layer 32. On the other hand, after the multiple etching, the thickness of the insulating layer 2 in the third block 23 is different from those in the first and second blocks 21, 22; it can be between the two or even thinner (as in the fourth block 24, which is an alternative block of the third block 23). Accordingly, a new semiconductor-fin height H₃ (or a new semiconductor-fin height H₄) is given for choices and providing layout widths with more linearity. Designers will be more flexible in controlling the driving current of FinFETs.

The steps according to the present invention allow using one or multiple additional mask to change the etched dept of the insulating layer 2 and enabling the exposed semiconductor fins to have various semiconductor-fin heights. By combining different semiconductor-fin heights, the fabricated FinFETs can have nearly arbitrary layout widths, approximating to planar MOSFETs. Thereby, the influence of the electron-channel-width quantization effect on circuits can be reduced substantially.

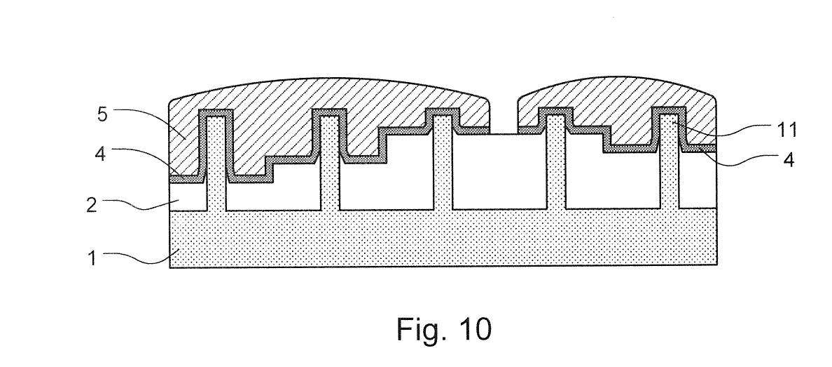

After the designed semiconductor-fin structure is fabricated, as shown in FIG. 10, a dielectric layer 4 is disposed on the plurality of semiconductor fins 11 for reducing leakage current. Then a gate 5 is disposed on the dielectric layer 4. This stage involves very mature deposition technology. In other words, the present invention can be totally compatible with the existing fabrication technology for FinFETs without increasing the difficulty in device fabrication. Only the number of mask processes is increased and the form of masks is altered.

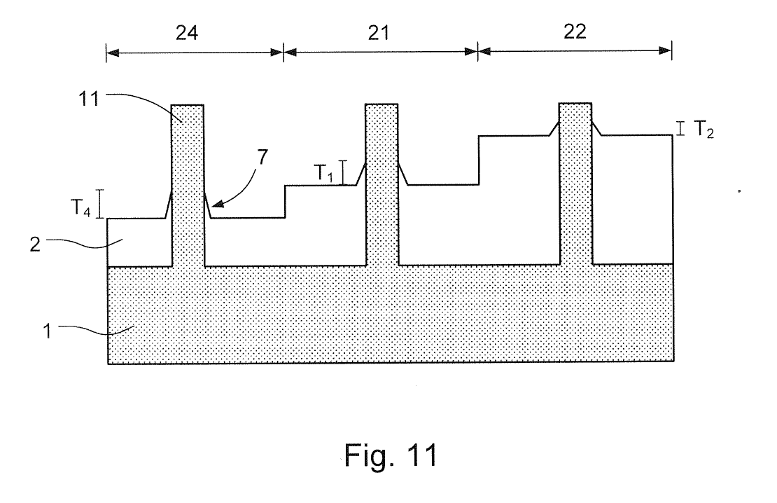

As shown in FIG. 11, the present invention further makes use of the taper structure produced during the etching process of the insulating layer 2 to enable more variations in the effective width of FinFETs. In addition to the semiconductor substrate 1, the insulating layers located on the semiconductor substrate 1 and having multiple blocks (in the figure, the first, second, and fourth blocks 21, 22, 24 are extracted and enlarged), and the semiconductor fins 11 grown upwards from the semiconductor substrate 1 and penetrating the insulating layer 2, the FinFET fabricated according to the present invention further includes a plurality of taper structures 7 located at and surrounding the junction between the insulating layer 2 and the semiconductor fins 11 due to wet etching. The plurality of taper structures 7 will cover a portion of the semiconductor fins 11 close to the bottom part.

The layout width is equal to the sum of two semiconductor-fin height H and one semiconductor-fin width W. Nonetheless, under the influence of the taper structures 7, it has to be considered while calculating the layout width that a part of the semiconductor fins 11 is covered by the taper structures 7. Thereby, each semiconductor-fin height H should be subtracted by the taper height. Furthermore, the insulating layer 2 according to the present invention includes blocks having differences in thickness after, multiple mask processes. The taper heights of the taper structures 7 in the blocks are different. For example, as shown in FIG. 11, the taper heights T₁, T₂, T₄ of the taper structures 7 produced by different wet etching processes in the first, second, and fourth blocks 21, 22, 24 are controlled to be different, making the design planning of layout width more flexible. More effective widths will be available. Alternatively, by using the taper heights, the number of lithography processes can be reduced. Accordingly, the production yield can be improved, the complexity in fabrication can be reduced, and thus achieving the purpose of mass production. The height-to-width ratio of the taper structures 7 described above ranges between 1:0.2 and 1:5.

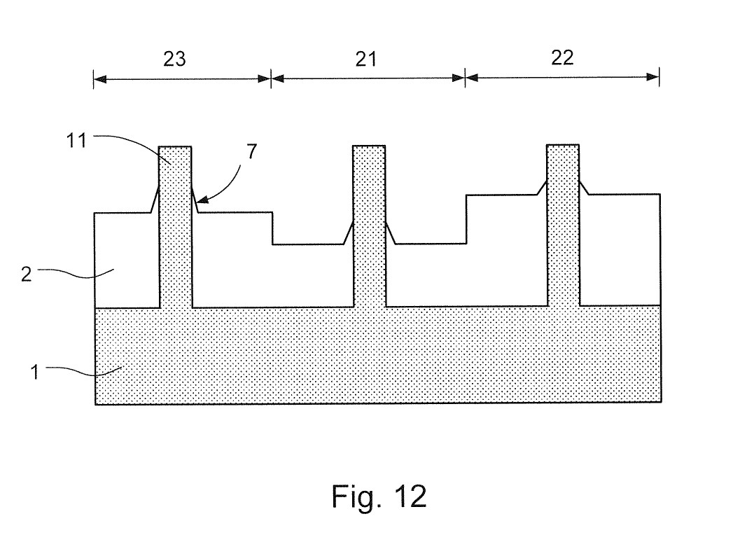

The structure shown in FIG. 12 is a special structure fabricated according to the novel process of the present invention. As shown in the figure, the insulating layer 2 includes the first, second, and third blocks 21, 22, 23 having differences in height after the lithography process using an extra mask. One of the three blocks can be lower than two adjacent blocks on both sides. The thickness of the insulating layer 2 in the first block 21 is smaller than those in the adjacent second block 22 and third block 23, and thus making the variation of the thickness of the insulating layer 2 non-gradual and irregular. This flexibility in structure is attributed to the high freedom in controlling the location of masks according to the fabrication method of the present invention. Thereby, more effective widths satisfying the requirements can be provided; the problem of electron-channel-width quantization is improved significantly.

In addition to improving the problem of electron-channel-width quantization, the present invention can further reduce the occupied planar area. Take fabricating SRAM, which comprises six transistors, for example. By using multiple mask processes according to the present invention, the six semiconductor-fin heights are different, endowing higher semiconductor fins 11 with zoom for shrinking their semiconductor-fin widths W. Accordingly, the device size of SRAM is reduced by 20% approximately. This is a breakthrough for developing system on chip (SoC).

To sum up, the present invention discloses a method for fabricating FinFETs and the structure thereof. The present invention provides the design concepts of multiple fin heights and defining locations for fins with different heights by mask. In addition, the taper structures produced by etching are used effectively as the variable for adjusting the effective width. It is distinct from the method for fabrication FinFET devices according to the prior art. The problem of electron-channel-width quantization is thus mitigated effectively. The present invention makes use of the existing fabrication process for silicon-based FinFETs; only one additional mask is required for defining the regions having high semiconductor-fin height and fabricating the structure by over-etching of STI. The FinFET device structure fabricated according to the present invention can be applied to manufacturing large-capacity embedded SRAM cells. The overall process is compatible with current fabrication technology in the semiconductor industry and easy for mass production with excellent performance. Thereby, the present invention undoubtedly provides a method for fabricating FinFETs with sufficient economic values.

Accordingly, the present invention conforms to the legal requirements owing to its novelty, nonobviousness, and utility. However, the foregoing description is only embodiments of the present invention, not used to limit the scope and range of the present invention. Those equivalent changes or modifications made according to the shape, structure, feature, or spirit described in the claims of the present invention are included in the appended claims of the present invention.

1. A structure of FinFET, comprising:
a semiconductor substrate;
an insulating layer, covering said semiconductor substrate, comprising a first block and a second block, and said first block and said second block having a difference in height;
a plurality of semiconductor fins, extending upwards from said semiconductor substrate and penetrating said insulating layer; and
a plurality of taper structures, surrounding the junctions of said plurality of semiconductor fins and said insulating layer, and covering a portion of said plurality of semiconductor fins;
wherein the semiconductor-fin heights of said plurality of semiconductor fins exposed above said insulating layer are different for said first block and said second block.

2. The structure of claim 1, wherein said insulating layer further comprises a third block, adjacent to said first block and said second block, and having differences in height with said first block and with said second block.

3. The structure of claim 2, wherein the semiconductor-fin heights of said semiconductor fins exposed above said insulating layer are different for said first block, said second block, and said third block.

4. The structure of claim 2, wherein the taper heights of said taper structures at the junctions between said semiconductor fins and said insulating layer are different for said first block, said second block, and said third block.

5. The structure of claim 1, wherein the height-to-width ratio of said taper structures ranges between 1:0.2 and 1:5.

6. The structure of claim 2, wherein the thickness of said insulating layer of one block in the group consisting of said first block, said second block, and said third block is smaller than the thicknesses of said insulating layers of the other two adjacent blocks in said group on both sides.

7. The structure of claim 1, wherein the layout width of said semiconductor fins are varied in non-integer multiples.

8. The structure of claim 1, wherein the different of the semiconductor-fin heights of said semiconductor fins exposed above said insulating layer between said first block and said second block is equal or higher than 25% of the semiconductor-fin height of said semiconductor fins exposed above said insulating layer in said first block.

9. A structure of FinFET, comprising:
a semiconductor substrate;
an insulating layer. covering said semiconductor substrate, comprising a first block and a second block, and said first block and said second block having a difference in height;
a plurality of semiconductor fins, extending upwards from said semiconductor substrate and penetrating said insulating layer; and
a plurality of taper structures, surrounding the junctions of said plurality of semiconductor fins and said insulating layer, and covering a portion of said plurality of semiconductor fins;
wherein the height-to-width ratio of said taper structures ranges between 1:0.2 and 1:5.

10. The structure of claim 9, wherein said insulating layer further comprises a third block, adjacent to said first block and said second block, and having differences in height with said first block and with said second block.

11. The structure of claim 10, wherein the semiconductor-fin heights of said semiconductor fins exposed above said insulating layer are different for said first block, said second block, and said third block.

12. The structure of claim 10, wherein the taper heights of said taper structures at the junctions between said semiconductor fins and said insulating layer are different for said first block, said second block, and said third block.

13. The structure of claim 10, wherein the thickness of said insulating layer of one block in the group consisting of said first block, said second block, and said third block is smaller than the thicknesses of said insulating layers of the other two adjacent blocks in said group on both sides.

14. The structure of claim 9, wherein the layout width of said semiconductor fins are varied in non-integer multiples.

15. A structure of FinFET, comprising:
a semiconductor substrate;
an insulating layer, covering said semiconductor substrate, comprising a first block, a second block and a third block, and said first block, said second block and said third block having differences in height;
a plurality of semiconductor fins, extending upwards from said semiconductor substrate and penetrating said insulating layer; and
a plurality of taper structures, surrounding the junctions of said plurality of semiconductor fins and said insulating layer, and covering a portion of said plurality of semiconductor fins;
wherein said third block is adjacent to said first block and said second block.

16. The structure of claim 15, wherein the semiconductor-fin heights of said semiconductor fins exposed above said insulating layer are different for said first block, said second block, and said third block.

17. The structure of claim 15, wherein the taper heights of said taper structures at the junctions between said semiconductor fins and said insulating layer are different for said first block, said second block, and said third block.

18. The structure of claim 15, wherein the thickness of said insulating layer of one block in the group consisting of said first block, said second block, and said third block is smaller than the thicknesses of said insulating layers of the other two adjacent blocks in said group on both sides.

19. The structure of claim 15, wherein the layout width of said semiconductor fins are varied in non-integer multiples.
